(19) United States
(12) Patent Application Publication
(10) Pub. No.: US 2018/0017781 A1
(43) Pub. Date: Jan. 18, 2018

(54) FRUSTRATED CUBE ASSEMBLY

(71) Applicant: Applied Materials, Inc., Santa Clara, CA (US)

(72) Inventors: David MARKLE, Pleasanton, CA (US); Thomas L. LAIDIG, Richmond, CA (US); Timothy N. THOMAS, Portland, OR (US); Jang Fung CHEN, Cupertino, CA (US)

(21) Appl. No.: 15/639,600

(22) Filed: Jun. 30, 2017

Related U.S. Application Data
(60) Provisional application No. 62/363,597, filed on Jul. 18, 2016.

(51) Int. Cl. G02B 26/08; G02B 5/04; G03F 7/20; G02F 1/13

(52) U.S. Cl. CPC G02B 26/0833; G03F 7/7015; G02B 5/04; G02F 1/1303

(57) ABSTRACT

The present disclosure generally relates to frustrated cube assemblies having a first prism having a first surface, a second surface, and a first hypotenuse, and a second prism having a third surface, a fourth surface, and a second hypotenuse. The first and second hypotenuses face one another and are separated by an air gap. The frustrated cube assembly may include a tilted mirror adjacent the second surface. The second surface may be a reflective diffraction grating. Light is reflected to a digital micromirror device (DMD) adjacent to the frustrated cube assembly at a normal incidence angle and through an image projection system along a single optical axis. The direction of light incident on the DMD is such that light reflected from an “on” mirror is directed along the normal to the DMD surface and at 45 degrees to the hypotenuses. The input and output light beams are parallel.

### CROSS-REFERENCE TO RELATED APPLICATIONS

This application claims benefit of U.S. Provisional Patent Application Ser. No. 62/363,597, filed on Jul. 18, 2016, which is herein incorporated by reference in its entirety.

### BACKGROUND

### Field

Embodiments of the present disclosure generally relate to apparatuses and systems for processing one or more substrates, and more specifically to apparatuses for performing photolithography processes.

### Description of the Related Art

Photolithography is widely used in the manufacturing of semiconductor devices and display devices, such as liquid crystal displays (LCDs). Large area substrates are often utilized in the manufacture of LCDs. LCDs, or flat panels, are commonly used for active matrix displays, such as computers, touch panel devices, personal digital assistants (PDAs), cell phones, television monitors, and the like. Generally, flat panels may include a layer of liquid crystal material forming pixels sandwiched between two plates. When power from the power supply is applied across the liquid crystal material, an amount of light passing through the liquid crystal material may be controlled at pixel locations enabling images to be generated.

Microlithography techniques are generally employed to create electrical features incorporated as part of the liquid crystal material layer forming the pixels. According to this technique, a light-sensitive photoresist is typically applied to at least one surface of the substrate. Then, a pattern generator exposes selected areas of the light-sensitive photoresist as part of a pattern with light to cause chemical changes to the photoresist in the selective areas to prepare these selective areas for subsequent development, which removes either the exposed or unexposed photoresist areas to create a mask, which resists or protects portions of the underlying layer from the etching process used to pattern the underlying layer and form the electrical features.

In order to continue to provide display devices and other devices to consumers at the prices demanded by consumers, new apparatuses and approaches are needed to precisely and cost-effectively create patterns on substrates, such as large area substrates.

### SUMMARY

The present disclosure generally relates to frustrated cube assemblies having a first prism having a first surface, a second surface, and a first hypotenuse, and a second prism having a third surface, a fourth surface, and a second hypotenuse. The first and second hypotenuses face one another and are separated by an air gap. The frustrated cube assembly may include a tilted mirror adjacent the second surface. The second surface may be a reflective diffraction grating. Light is reflected to a digital micromirror device (DMD) adjacent to the frustrated cube assembly at a normal incidence angle and through an image projection system along a single optical axis. The direction of light incident on the DMD is such that light reflected from an “on” mirror is directed along the normal to the DMD surface and at 45 degrees to the hypotenuses. The input and output light beams are parallel.

In one embodiment, a frustrated cube assembly is disclosed. The frustrated cube assembly includes a first prism, a second prism, and a tilted mirror. The first prism includes a first surface, a second surface and a first hypotenuse. The second prism includes a third surface, a fourth surface and a second hypotenuse. The first hypotenuse and the second hypotenuse are facing one another and are separated by an air gap. The tilted mirror is adjacent the second surface and the tilted mirror and the second surface are spaced apart by a second air gap.

In another embodiment, a frustrated cube assembly is disclosed. The frustrated cube assembly includes a first prism, a second prism, a tilted mirror, and a digital micromirror device. The first prism includes a first surface, a second surface, and a first hypotenuse. The second surface is a window and the second surface is sloped. The second prism includes a third surface, a fourth surface and a second hypotenuse. The first hypotenuse and the second hypotenuse are facing one another and are separated by a first air gap. The tilted mirror is adjacent the second surface and the tilted mirror and the second surface are spaced apart by a second air gap. The digital micromirror device is adjacent the third surface.

In yet another embodiment, a frustrated cube assembly is disclosed. The frustrated cube assembly includes a first prism and a second prism. The first prism includes a first surface, a second surface and a first hypotenuse. The second surface is a reflective diffraction grating. The second prism includes a third surface, a fourth surface and a second hypotenuse. The first hypotenuse and the second hypotenuse are facing one another and are separated by an air gap.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a perspective view of a system that may benefit from embodiments disclosed herein.

FIG. 2 is a schematic view of an illumination system of an image projection system that may benefit from embodiments disclosed herein.

FIG. 3 is a perspective view of an image projection apparatus that may benefit from embodiments disclosed herein.

FIG. 4 is a schematic view of a frustrated cube assembly according to one embodiment.

FIG. 5 is a schematic view of a frustrated cube assembly according to another embodiment.

FIG. 6 is a schematic view of a mirror array of a digital micromirror device according to one embodiment.

FIG. 7 is a cross-sectional view of one of the optical relays according to one embodiment.

To facilitate understanding, identical reference numerals have been used, wherever possible, to designate identical elements that are common to the Figures. Additionally, elements of one embodiment may be advantageously adapted for utilization in other embodiments described herein.

### DETAILED DESCRIPTION

The present disclosure generally relates to frustrated cube assemblies having a first prism having a first surface, a second surface, and a first hypotenuse, and a second prism having a third surface, a fourth surface, and a second hypotenuse. The first and second hypotenuses face one another and are separated by an air gap. The frustrated cube assembly may include a tilted mirror adjacent the second surface. The second surface may be a reflective diffraction grating. Light is reflected to a digital micromirror device (DMD) adjacent to the frustrated cube assembly at a normal incidence angle and through an image projection system along a single optical axis. The direction of light incident on the DMD is such that light reflected from an “on” mirror is directed along the normal to the DMD surface and at 45 degrees to the hypotenuses. The input and output light beams are parallel.

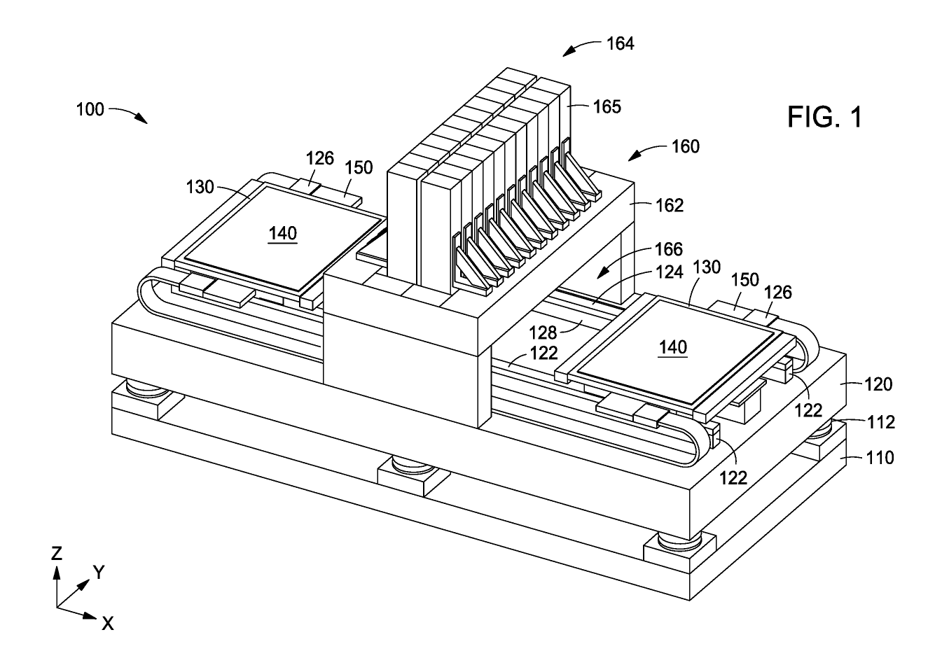

FIG. 1 is a perspective view of a system 100 that may benefit from embodiments disclosed herein. The system 100 includes a base frame 110, a slab 120, two or more stages 130, and a processing apparatus 160. The base frame 110 may rest on the floor of a fabrication facility and may support the slab 120. Passive air isolators 112 may be positioned between the base frame 110 and the slab 120. The slab 120 may be a monolithic piece of granite, and the two or more stages 130 may be disposed on the slab 120. A substrate 140 may be supported by each of the two or more stages 130. A plurality of holes (not shown) may be formed in the stage 130 for allowing a plurality of lift pins (not shown) to extend therethrough. The lift pins may rise to an extended position to receive the substrate 140, such as from one or more transfer robots (not shown). The one or more transfer robots may be used to load and unload a substrate 140 from the two or more stages 130.

The substrate 140 may, for example, be made of glass and be used as part of a flat panel display. In other embodiments, the substrate 140 may be made of other materials. In some embodiments, the substrate 140 may have a photoresist layer formed thereon. A photoresist is sensitive to radiation and may be a positive photoresist or a negative photoresist, meaning that portions of the photoresist exposed to radiation will be respectively soluble or insoluble to photoresist developer applied to the photoresist after the pattern is written into the photoresist. The chemical composition of the photoresist determines whether the photoresist will be a positive photoresist or negative photoresist. For example, the photoresist may include at least one of diazonaphthoquinone, a phenol formaldehyde resin, poly(methyl methacrylate), poly(methyl glutarimide), and SU-8. In this manner, the pattern may be created on a surface of the substrate 140 to form the electronic circuitry.

The system 100 may further include a pair of supports 122 and a pair of tracks 124. The pair of supports 122 may be disposed on the slab 120, and the slab 120 and the pair of supports 122 may be a single piece of material. The pair of tracks 124 may be supported by the pair of the supports 122, and the two or more stages 130 may move along the tracks 124 in the X-direction. In one embodiment, the pair of tracks 124 is coplanar with a pair of parallel magnetic channels. As shown, each track 124 of the pair of tracks 124 is linear. In other embodiments, the track 124 may have a non-linear shape. An encoder 126 may be coupled to each stage 130 in order to provide location information to a controller (not shown).

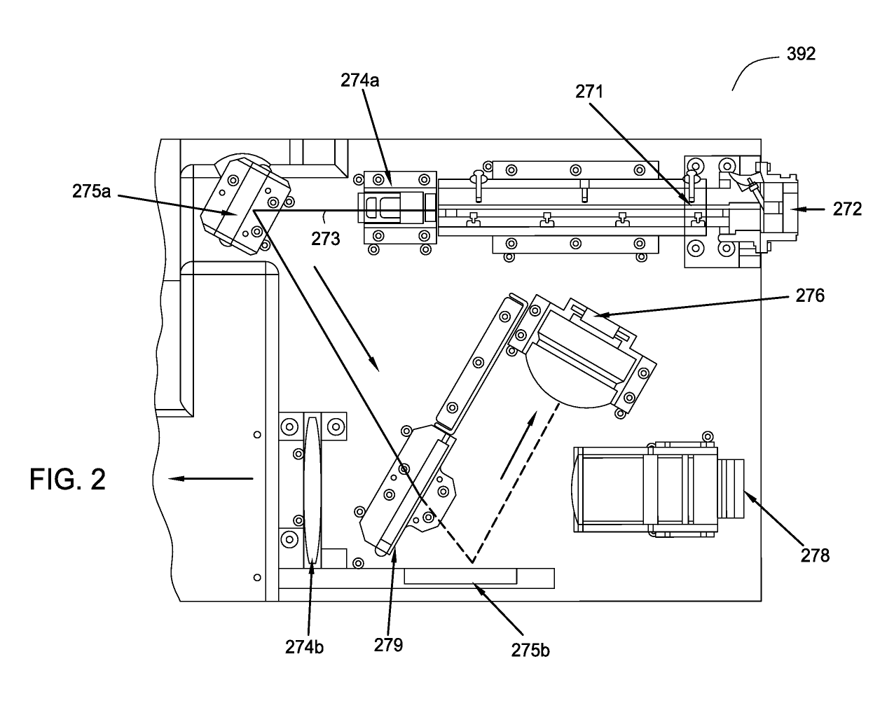

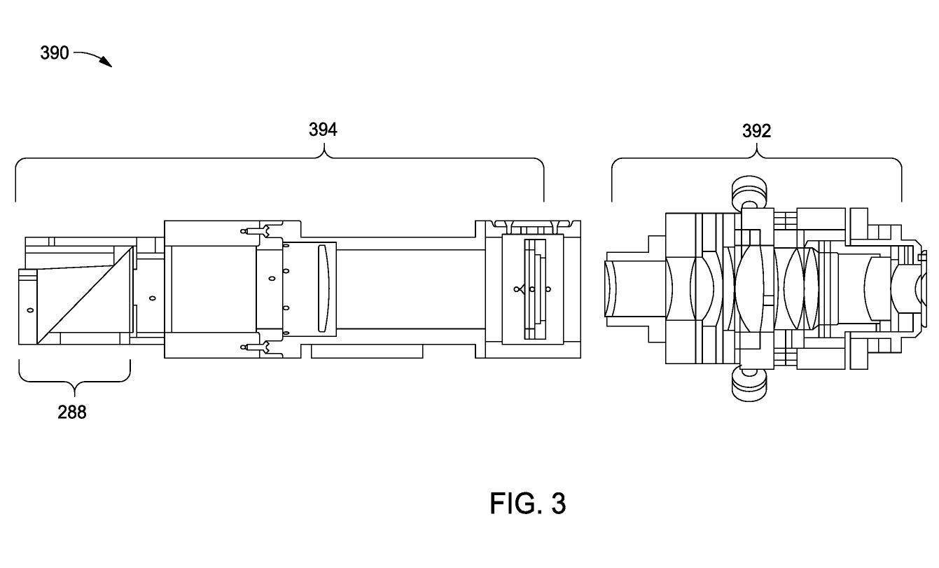

The processing apparatus 160 may include a support 162 and a processing unit 164. The support 162 may be disposed on the slab 120 and may include an opening 166 for the two or more stages 130 to pass under the processing unit 164. The processing unit 164 may be supported by the support 162. In one embodiment, the processing unit 164 is a pattern generator configured to expose a photoresist in a photolithography process. In some embodiments, the pattern generator may be configured to perform a maskless lithography process. The processing unit 164 may include a plurality of image projection apparatuses (shown in FIGS. 2-3). In one embodiment, the processing unit 164 may contain 84 image projection apparatuses. Each image projection apparatus is disposed in a case 165. The processing apparatus 160 may be utilized to perform maskless direct patterning. During operation, one of the two or more stages 130 moves in the X-direction from a loading position, as shown in FIG. 1, to a processing position. The processing position may refer to one or more positions of the stage 130 as the stage 130 passes under the processing unit 164. During operation, the two or more stages 130 may be supported by a plurality of air bearings (not shown) and may move along the pair of tracks 124 from the loading position to the processing position. A plurality of guide air bearings (not shown) may be coupled to each stage 130 and positioned adjacent an inner wall 128 of each support 122 in order to stabilize the movement of the stage 130 in the Y-direction. Each of the two or more stages 130 may also move in the Y-direction by moving along a track 150 for processing and/or indexing the substrate 140. Each of the two or more stages 130 is capable of independent operation and can scan a substrate 140 in one direction and step in the other direction. In some embodiments, when one of the two or more stages 130 is scanning a substrate 140, another of the two or more stages 130 is unloading an exposed substrate 140 and loading the next substrate 140 to be exposed.

A metrology system measures the X and Y lateral position coordinates of each of the two or more stages 130 in real time so that each of the plurality of image projection apparatuses can accurately locate the patterns being written in the photoresist covered substrate 140. The metrology system also provides a real-time measurement of the angular position of each of the two or more stages 130 about the vertical or Z-axis. The angular position measurement can be used to hold the angular position constant during scanning by means of a servo mechanism or it can be used to apply corrections to the positions of the patterns being written on the substrate 140 by the image projection apparatus. These techniques may be used in combination.

FIG. 2 is a schematic view of an illumination system 392 of an image projection system that may benefit from embodiments described herein. The illumination system 392 may include a light source 272, a light pipe 271, a plurality of lenses (two are shown) 274a, 274b, a plurality of mirrors (two are shown) 275a, 275b, a beamsplitter 279, an illumination intensity detector 276, and a white light diode 278. The light source 272 may be a light emitting diode (LED) or a laser, and the light source 272 may be capable of producing a light having predetermined wavelength. In one embodiment, the predetermined wavelength is in the blue or near ultraviolet (UV) range, such as less than about 450 nm.

During operation, a light beam 273 having a predetermined wavelength, such as a wavelength in the blue range, is produced by the light source 272. The light beam 273 travels through the light pipe 271 and is reflected off of the mirror 274a to the beamsplitter 279. The light beam 273 is then projected out of the illumination system 392 towards the frustrated cube assembly 288 of the projection system 394, which is shown in FIG. 3.

FIG. 3 is a cross-sectional view of an image projection apparatus 390 that may benefit from embodiments disclosed herein. The illumination enters the image projection apparatus 390 from the left hand side, where the frustrated cube assembly 288 is located, and exits on the right side, where a substrate is located. The projection system 394 includes a frustrated cube assembly 288. The projection systems may also include various subcomponents (not labeled), including, but not limited to, a beamspiltter, a focus sensor, a detector array for viewing the substrate, one or more image transducers, a focus motor, a focus group, and a projection window.

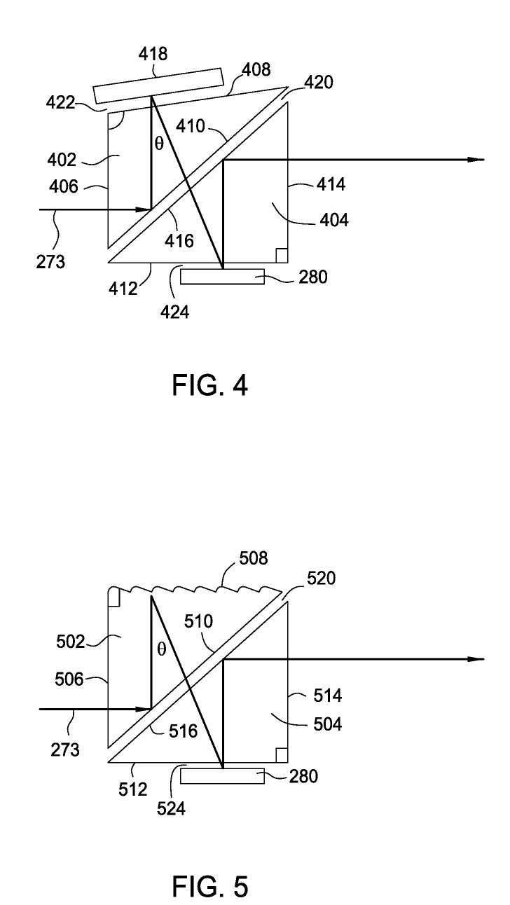

The frustrated cube assembly 288 may have various embodiments as shown in FIGS. 4 and 5. FIG. 4 is a schematic view of a frustrated cube assembly 400 according to one embodiment. Frustrated cube assembly 400 includes a first prism 402 and a second prism 404. The first prism 402 has a first surface 406, a second surface 408 and a first hypotenuse 410. The second prism 404 has a third surface 412, a fourth surface 414 and a second hypotenuse 416. The first prism 402 and the second prism 404 may be offset from one another such that the corner of intersection of the first surface 406 and the first hypotenuse 410 is offset from the corner of intersection of the third surface 412 and the second hypotenuse 416. Similarly, the corner of intersection of the second surface 408 and the first hypotenuse 410 is offset from the corner of intersection of the fourth surface 414 and the second hypotenuse 416. The first surface 406 and the second surface 408 intersect at an angle greater than 90 degrees. The third surface 412 and fourth surface 414 are perpendicular to one another and therefore intersect at an angle of 90 degrees. The first hypotenuse 410 and second hypotenuse 416 are facing one another and are separated by a first air gap 420. The first air gap 420 may be evenly spaced throughout. The frustrated cube assembly 400 also includes a tilted mirror 418. The tilted mirror is adjacent the second surface 408. The tilted mirror 418 and the second surface 408 are separated by a second air gap 422. In one embodiment, the long axis of the tilted mirror 418 is parallel to the second surface 408. In another embodiment, the long axis of the tilted mirror 418 is not parallel to the second surface 408. In other words, the second air gap 422 may be evenly spaced throughout. The frustrated cube assembly 400 further includes a DMD 280. The DMD 280 may be adjacent the third surface 412. The DMD 280 may be spaced apart from the third surface 412 by a DMD air gap 424. The DMD air gap 424 may be evenly spaced throughout.

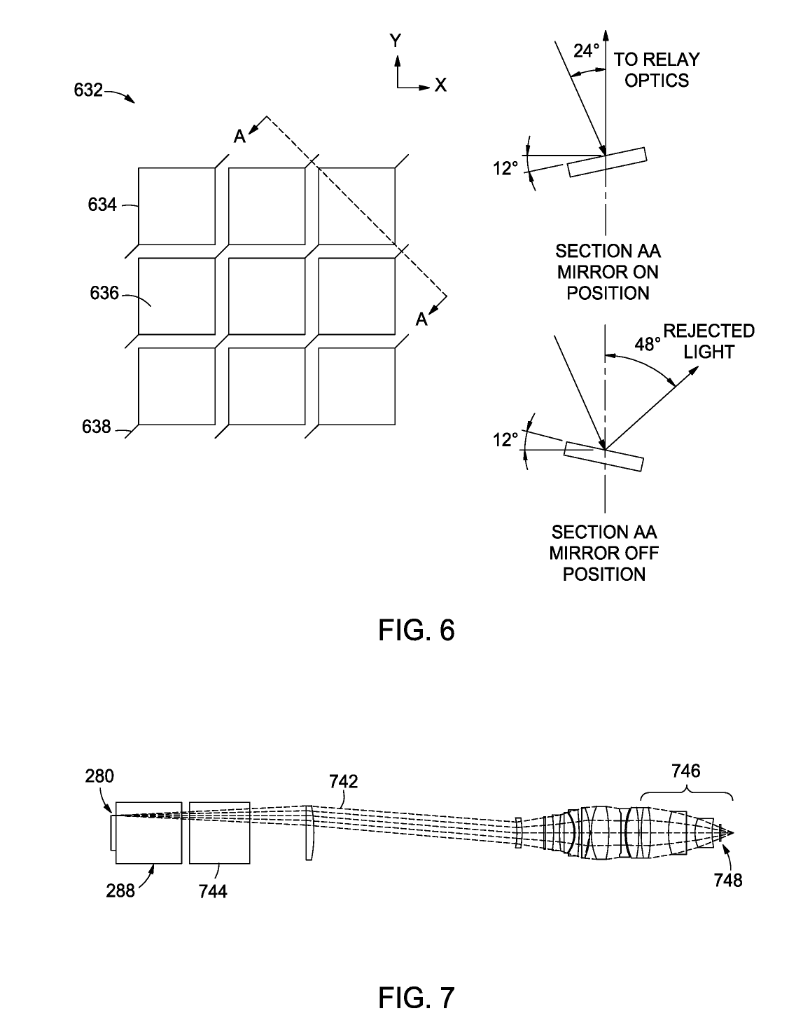

The DMD 280 includes a plurality of micromirrors 634 which are arranged in a mirror array 632, as shown in FIG. 6. The edges 636 of micromirrors 634 are arranged along orthogonal axes, which may be the X axis and the Y axis. These axes are congruent with similar axis referenced to the substrate 140 or a stage coordinate system after taking into account a 90 degree fold introduced by the frustrated cube assembly 288. However, the hinges 638 on each micromirror 634 are located on opposing corners of each mirror causing it to pivot on an axis at 45 degrees to the X axis and Y axis. Each of the plurality of micromirrors 634 may be tilted an angle relative to the horizontal surface of the mirror array 632. These mirrors can be switched between on and off positions by varying the angle of tilt of the mirror. Depending on whether the light hits a mirror that is turned on or off, the light will either be sent through the rest of the image projection apparatus 390, or it will be unused, respectively. In one embodiment, the unused light is directed into a light dump (not shown). In one embodiment, the DMD 280 is made such that the only stable position for each micromirror 634 is at a tilt angle of plus or minus 12 degrees with respect to the surface of the mirror array 632. In order to reflect incident light normal to the surface of the mirror array 632, the incident light has to be incident at twice the mirror tilt angle (24 degrees) and in an incident plane rotated at 45 degrees with respect to the X and Y axes. The DMD 280 is positioned to be flat to the projection of the substrate 140. In other words, the tilt direction of the tilted mirror 418 or the direction of the grating lines in grating 508 have to be rotated 45° about a vertical axis to generate an illumination beam on the DMD 280, which is reflected by a tilted micromirror 634 into a vertical direction and then reflected down the center of the projection system 394.

The tilted mirror 418 may be tilted at a second angle relative to the second surface 408. This adjustment is used to vary the incidence angle of the illumination beam on the DMD micromirrors 634 so it is equal to twice the DMD mirror tilt angle, which can vary by ±1°. The first angle and the second angle may be equal and opposite with respect to a normal to a surface of the DMD 280.

In operation, light beam 273 enters the frustrated cube assembly through the first surface 406. The light beam 273 is then reflected off of the first hypotenuse 410 and up through the second surface 408. The second surface 408 may be a window such that the light beam 273 passes through the second surface 408 to the tilted mirror 418. The light beam 273 is then reflected off of the tilted mirror 418 at an angle (θ) and through the second surface 408, the first hypotenuse 410, the first air gap 420, the second hypotenuse 416 and the third surface 412 to the DMD 280. The tilted mirror 418 provides a fine correction to the direction of the illumination beam incident on the DMD to correct for variations in the DMD micromirror tilt angle. The light beam 273 is then reflected off the DMD 280 through the third surface 412 to the second hypotenuse 416.

The light beam 273 is then reflected off of the second hypotenuse 416 and through the fourth surface 414 and into the projection system 394, through which it is ultimately transmitted to the substrate 140.

The second surface 408, or the tilted mirror 418, is sloped at a same angle to an angle of a digital micromirror of the digital micromirror device. For example if the tilt of the micromirrors 634 is +/−12 degrees then the tilted mirror 418 has to be tilted 12 degrees so the light beam 273 reflected from it is tilted at 24 degrees (angles double on reflection). The 24 degree angle is sufficient to allow the light beam 273 to pass through the first air gap 420 and is at an angle so that the reflection from a DMD “on” mirror tilted at, for example, +12 degrees reflects normal to the DMD 280 and is totally reflected from the 45 degree surface at the first air gap 420. The light beam 273 that strikes a DMD “off” mirror tilted at −12 degrees is reflected at 12+24 degrees from the mirror normal and 48 degrees from the DMD normal. This unwanted illumination is dumped into a light dump. The tilt axis of the micromirrors 634 is rotated 45 degrees with respect to the rectangular dimensions of the DMD 280 and the usual Z and X axis. Therefore, the tilt direction of tilted mirror 418 also has to be rotated 45 degrees. As a consequence of the tilt direction of the last fold mirror in the path of light beam 273, the axis of the path prior to entering the frustrated cube assembly 400 is offset in both X and Y directions from the axis of the projection system located on the other side of the frustrated cube assembly 400.

Furthermore, there may be a slight variation in the tilt angle from one DMD to another. For example, the variation may be +/−1 degree. Because the tilted mirror 418 is spaced apart from the second surface 408, the variation can be accommodated for by slightly changing the tilt angle of the tilted mirror 418. For example, the tilt angle of the tilted mirror 418 may be changed by +/−1 degree in order to maintain the angle of reflection from the micromirrors normal to the plane of the DMD.

FIG. 5 is a schematic view of a frustrated cube assembly 500 according to another embodiment. Frustrated cube assembly 500 includes a first prism 502 and a second prism 504. The first prism 502 has a first surface 506, a second surface 508 and a first hypotenuse 510. The second prism 504 has a third surface 512, a fourth surface 514 and a second hypotenuse 516. The first prism 502 and the second prism 504 may be offset from one another such that the corner of intersection of the first surface 506 and the first hypotenuse 510 is offset from the corner of intersection of the third surface 512 and the second hypotenuse 516. Similarly, the corner of intersection of the second surface 508 and the first hypotenuse 510 is offset from the corner of intersection of the fourth surface 514 and the second hypotenuse 516. The first hypotenuse 410 and second hypotenuse 516 are facing one another and are separated by a first air gap 520. The first surface 506 and the second surface 508 are perpendicular to one another and intersect at a 90 degree angle. The third surface 512 and the fourth surface 514 are perpendicular to one another and intersect at a 90 degree angle. The second surface 508 may be a reflective diffraction grating. Diffraction from the grating surface 508 results in a diffraction angle (θ). The relationship between the grating spacing and the angle of diffraction is determined by Equation 1, the grating equation.

mλ=d(sin θ) Equation 1

In Equation 1, m is an integer determining the diffraction order, A is the wavelength, d is the grating period and θ is the diffraction angle.

The grating of the second surface 508 may be produced by any suitable process for generating a grating, including lithography and etching processes. The grating is etched into the second surface 508 such that the height of the first prism 502 may be different than the height of the second prism 504. The frustrated cube assembly 500 further includes a DMD 280. The DMD 280 may be adjacent the third surface 512. The DMD 280 may be spaced apart from the third surface 512 by a DMD air gap 524. The DMD air gap 524 may be evenly spaced throughout.

In operation, light beam 273 enters the frustrated cube assembly through the first surface 506. The light beam 273 is then reflected off of the first hypotenuse 510 and up to the second surface 508. The light beam 273 is then diffracted from the second surface 508, and through the first hypotenuse 510, the air gap 520, the second hypotenuse 516 and the third surface 512 to the DMD 280. The light beam 273 is then reflected off of a DMD 280 on-mirror through the third surface 512 to the second hypotenuse 516. The light beam 273 is then reflected off of the second hypotenuse 516, through the fourth surface 514 and into the projection system 394, which ultimately projects the light beam 273 onto the substrate 140.

FIG. 7 is a cross-sectional view of the optical relay 742 according to one embodiment. The optical elements comprising relay 742 are aligned along a single optical axis that passes through the frustrated cube assembly 288, DMD 280 and the beamsplitter 744, and the refractive lens components. The pattern generated by the DMD 280 is ultimately projected onto the substrate through the focus group 746 and projection window 748.

The frustrated cube assembly 288 helps to minimize the footprint of each image projection apparatus 390 by keeping the direction of the flow of illumination roughly normal to the substrate 140 all the way from the light source 272 that generates the exposure illumination to the substrate focal plane.

Use of the frustrated cube assembly in an image projection apparatus results in minimum light loss and allows many projection systems to be placed side by side across the width of a flat panel substrate. Accordingly, multiple image projection apparatuses may be aligned in a single system. More specifically, tuning the angle of the tilted mirror accommodates variations in the average tilt angle in the DMD micromirrors and aligns the direction of the light reflected from the micromirrors with the optical axis, such that the input light beam is parallel to the output light beam.

While the foregoing is directed to embodiments of the present disclosure, other and further embodiments of the disclosure may be devised without departing from the basic scope thereof, and the scope thereof is determined by the claims that follow.

What is claimed is:

1. A frustrated cube assembly, comprising:
a first prism, wherein the first prism comprises:
a first surface;
a second surface; and
a first hypotenuse;
a second prism, wherein the second prism comprises:
a third surface;
a fourth surface; and
a second hypotenuse, wherein the first hypotenuse and the second hypotenuse are facing one another, and wherein the first hypotenuse and the second hypotenuse are separated by a first air gap; and
a tilted mirror, wherein the tilted mirror is adjacent the second surface, and wherein the tilted mirror and the second surface are spaced apart by a second air gap.

2. The frustrated cube assembly of claim 1, further comprising:
a digital micromirror device, wherein the digital micromirror device is adjacent the third surface.

3. The frustrated cube assembly of claim 2, wherein the first surface and the second surface intersect at an angle greater than about 90 degrees, and wherein the third surface and the fourth surface are perpendicular.

4. The frustrated cube assembly of claim 3, wherein the second surface is a window.

5. The frustrated cube assembly of claim 4, wherein the second surface is sloped with respect to the third surface.

6. The frustrated cube assembly of claim 5, wherein the second surface is sloped at a same angle to an angle of a digital micromirror of the digital micromirror device.

7. The frustrated cube assembly of claim 5, wherein the tilted mirror is parallel to the second surface.

8. A frustrated cube assembly, comprising:
a first prism, wherein the first prism comprises:
a first surface;
a second surface, wherein the second surface is a window, and wherein the second surface is sloped; and
a first hypotenuse;
a second prism, wherein the second prism comprises;
a third surface;
a fourth surface; and
a second hypotenuse, wherein the first hypotenuse and the second hypotenuse are facing one another, and wherein the first hypotenuse and the second hypotenuse are separated by a first air gap;
a tilted mirror, wherein the tilted mirror is adjacent the second surface, and wherein the tilted mirror and the second surface are spaced apart by a second air gap; and
a digital micromirror device, wherein the digital micromirror device is adjacent the third surface.

9. The frustrated cube assembly of claim 8, wherein the digital micromirror device comprises a plurality of mirrors.

10. The frustrated cube assembly of claim 9, wherein each mirror of the plurality of mirrors of the digital micromirror device may be tilted a first angle relative to a horizontal surface of the digital micromirror device.

11. The frustrated cube assembly of claim 10, wherein the tilted mirror is at a second angle relative to the first surface.

12. The frustrated cube assembly of claim 11, wherein the first angle and the second angle are equal and opposite with respect to a normal to a surface of the digital m icrom irror device.

13. The frustrated cube assembly of claim 12, wherein the second surface is tilted 12 degrees so that a central illumination beam is incident on the digital micromirror device at 24 degrees, and wherein the second surface is normal to a tilt axis of the plurality of mirrors of the digital micromirror device.

14. The frustrated cube assembly of claim 13, wherein the tilted mirror is parallel to the second surface.

15. A frustrated cube assembly, comprising:
a first prism, wherein the first prism comprises:
a first surface;
a second surface, wherein the second surface is a reflective diffraction grating; and
a first hypotenuse; and
a second prism, wherein the second prism comprises;
a third surface;
a fourth surface; and
a second hypotenuse, wherein the first hypotenuse and the second hypotenuse are facing one another, and wherein the first hypotenuse and the second hypotenuse are separated by an air gap.

16. The frustrated cube assembly of claim 15, wherein the first surface and the fourth surface are parallel.

17. The frustrated cube assembly of claim 16, wherein the second surface and the third surface are parallel.

18. The frustrated cube assembly of claim 17, wherein the first surface and the second surface are perpendicular to one another.

19. The frustrated cube assembly of claim 15, wherein a direction of grating lines of the reflective diffraction grating is rotated 45 degrees about a vertical axis.

20. The frustrated cube assembly of claim 15, further comprising:
a digital micromirror device, wherein the digital micromirror device is adjacent the third surface.
